(19) United States
(12) Patent Application Publication
(10) Pub. No.: US 2008/0044572 A1
(43) Pub. Date: Feb. 21, 2008

(54) RIGHT-SIZED VACUUM PRECURSOR (RSVP) DISTILLATION SYSTEM

(76) Inventors: Stephen D. Loeffler, Holland, PA (US); Seth B. Wolf, Fort Washington, PA (US); Charles W. Albrecht, Furlong, PA (US); John J. Brennan, Perkasie, PA (US)

Correspondence Address: DON W. BULSON (PARKER HANNIFIN);RENNER, OTTO, BOISSELLE & SKLAR, LLP, 1621 EUCLID AVENUE / 19TH FLOOR, CLEVELAND, OH, 44115, US

(21) Appl. No.: 11/839,068

(22) Filed: Aug. 15, 2007

Related U.S. Application Data
(60) Provisional application No. 60/822,401, filed on Aug. 15, 2006.

(51) Int. Cl. C23C 16/00; B01D 3/00

(52) U.S. Cl. 427/255.28; 203/91; 203/99

(57) ABSTRACT

A method for purifying a precursor material for use in a chemical vapor deposition system comprising providing a precursor material suitable for chemical vapor deposition, and distilling the precursor material to provide, as a distillate, a purified precursor material from which at least one non-volatile component, at least one metal impurity, or a combination thereof has been removed. The method may be used to purify siloxane and silane precursor materials and reduce clogging of chemical vapor deposition components.

### CROSS-REFERENCE TO RELATED APPLICATIONS

The present application claims the benefit of the filing date of U.S. Provisional Application Ser. No. 60/822,401, filed Aug. 15, 2006, the entire disclosure of which is incorporated herein by reference.

### TECHNICAL FIELD

The present invention relates broadly to a method for purifying precursor materials for use in chemical vapor deposition processes and a system for purifying precursor materials.

### BACKGROUND

High purity fluid processing applications may be employed to deposit high purity films, such as metal based films, on a substrate. Examples of such fluid processing applications include spray coating, spin coating, sol-gel deposition, chemical vapor deposition (CVD), and the like. Chemical vapor deposition is an increasingly utilized delivery process for forming solid materials, such as coatings or powders, by way of reactants in a vapor phase. Typically, a precursor material is vaporized by heating to an appropriate temperature and bubbling a flow of carrier gas through the liquid to transport the vapor into a CVD chamber. The vapor is transported to a substrate and contacted with the substrate under conditions sufficient to deposit a thin film onto the substrate.

Chemical vapor deposition is widely used in the semiconductor manufacturing industry to provide a metal coating on a semiconductor device. For a semiconductor device to perform properly, it is best for the coating to have a very high purity. Consequently, the precursor material to be used in the chemical vapor deposition process should have a very high purity (on a metal contaminants basis) such as, for example, at least 99.5% and even 99.99% or higher. Precursors, which are typically obtained in bulk from a supplier, are often expensive materials, and the cost increases for higher purity materials.

In addition to the high cost associated with high purity precursors, certain classes of precursors may present problems in the delivery of the precursor during the chemical vapor deposition process. Silanes and siloxanes have been used for precursor materials for performing CVD on a substrate. But a problem with these materials has been formation of a residue that clogs delivery tubes and other components in the CVD system. The clogging causes unreliable or non-reproducible delivery of precursor material to the CVD system, which may cause a high field failure rate of mechanisms in liquid delivery systems. This problem has perplexed those in the industry, as the silane and siloxane precursor materials are typically high purity materials often having a purity of at least about 99.99%

### SUMMARY

The present invention provides a method and system for purifying precursor materials prior to introduction into a high purity fluid processing application such as, for example, chemical vapor deposition. In general, the method includes providing a precursor material having one or more impurities and distilling the precursor material to produce, as a distillate, a purified precursor material.

The method includes providing a precursor material suitable for chemical vapor deposition, and distilling the precursor material to provide, as a distillate, a purified precursor material from which at least one non-volatile component, at least one metal impurity, or a combination thereof has been removed. The present invention provides a method that reduces, if not eliminates, clogging of CVD components by distilling a precursor material to remove impurities that have been found to be the source of the clogging. This is surprising in that prior processes used high purity precursor material including material having a purity of at least 99.99%.

The method is carried out by a distillation process and does not require the distillation to be an azeotropic distillation. The distillation may be performed as a vacuum distillation, by applying a vacuum to the distillation system and carrying out the distillation at a pressure below atmospheric pressure. The distillation may be carried out at a pressure below about 150 torr.

The precursor material may be any material suitable for depositing a desired film on a substrate via chemical vapor deposition. The method is suitable for use with siloxane and silane precursor materials such as, for example, tetramethylcyclotetrasiloxane, tetraethoxysilane, and the like.

The method provides for the removal of non-volatile impurities from precursor materials that may clog the components of a chemical vapor deposition apparatus. The method also provides for the removal of metal impurities that may be considered as contaminants if deposited on the substrate during a chemical vapor deposition. The method may allow less expensive, lower purity precursor materials to be purchased from suppliers and subsequently purified to provide a precursor material of a desired purity.

The purification may be performed at the precursor supplier's site or at the same location at which the chemical vapor deposition process is carried out. The distillation may be performed using a self-contained distillation apparatus. The self-contained distillation system may be used as a filling station to collect purified precursor material for use at a later time. The self-contained distillation system may also be connected to a chemical vapor deposition apparatus to supply the purified precursor material directly from the distillation apparatus to a chemical vapor deposition apparatus. The system may be configured to provide a substantially continuous flow of purified precursor material to a chemical vapor deposition apparatus.

The present invention also provides a method for depositing a coating on a substrate by chemical vapor deposition by delivering a purified precursor material obtained by the purification process in accordance with the present invention to a chemical vapor deposition apparatus, vaporizing the purified precursor, and contacting the purified precursor vapor with a substrate to deposit a desired coating on the substrate.

The present invention also provides a chemical vapor deposition system comprising a distillation system for purifying a precursor material; and a chemical vapor deposition apparatus; wherein the distillation system comprises a distillation vessel; a fluid inlet in fluid communication with the distillation vessel for delivering a precursor material to the distillation vessel; a condenser; at least one receiver for receiving a purified precursor material obtained by distilling a precursor material; a gas inlet in fluid communication with the at least one receiver for introducing a gas into the at least one receiver and pressurizing the at least one receiver to facilitate the flow of the purified precursor material to the high purity fluid processing system; and an outlet in fluid communication with the chemical vapor deposition apparatus.

The foregoing and other features of the invention are hereinafter described in detail in conjunction with the accompanying drawings which set forth exemplary embodiments illustrating a few of the various ways in which the principles of the invention may be employed.

### BRIEF DESCRIPTION OF THE DRAWINGS

In the annexed drawings:

FIG. 1 is a schematic representation of an exemplary chemical vapor deposition system employing an distillation system for purifying a precursor material in accordance with the present invention; and

FIG. 2 is a perspective view of an exemplary distillation system for purifying a precursor material.

### DETAILED DESCRIPTION

The present invention provides a method and system for purifying precursor materials prior introduction into a high purity fluid processing application such as, for example, chemical vapor deposition. In general, the method includes providing a precursor material having one or more impurities and distilling the precursor material to produce, as a distillate, a purified precursor material.

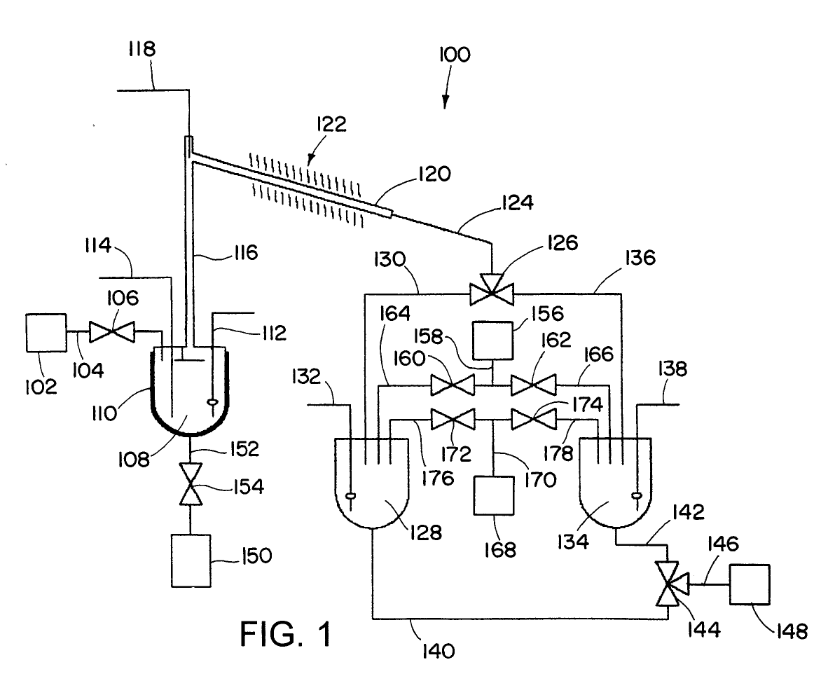

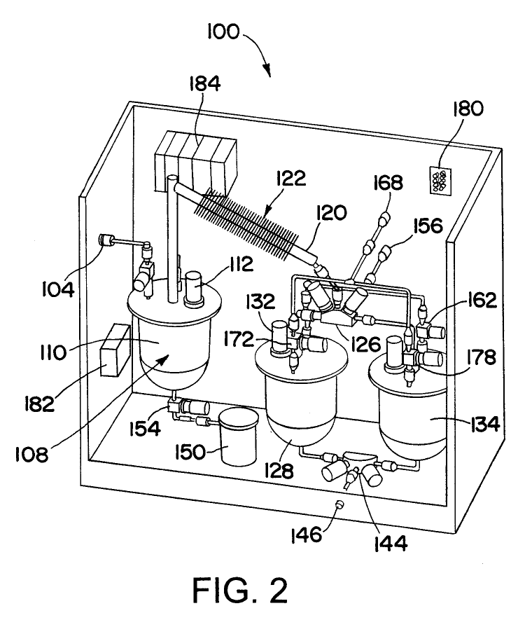

An exemplary method and system for purifying a precursor material may be understood with reference to FIGS. 1 and 2. With reference to FIG. 1, an exemplary distillation system 100 includes a distillation vessel 108, a distillation column 116, a condenser 120, a first receiver 128, and a second receiver 134. Generally, a precursor material is supplied from a precursor feedstock 102 through a line or inlet 104 to the distillation vessel 108. The precursor material is heated, such as by heating the vessel 108 using a heater jacket 110, to a suitable temperature to cause the precursor material to vaporize. The vapor climbs up the column 116 and condenses at the junction between the column 116 and the condenser 120. The condenser tube is cooled, such as by cooling fins 122, and the precursor vapor condenses back to a liquid and passes through a line 124 and into a receiver such as one of receivers 128 or 134 via lines 130 or 136, respectively. The liquid received in the receivers 128 and/or 134 is a purified precursor material.

The purified precursor material may then be transported to a high purity fluid processing application such as, for example, a chemical vapor deposition system. As shown in FIG. 1, the distillation system 100 may be coupled to a chemical vapor deposition apparatus 148. The distillation system may include lines 140 and 142 for delivering purified precursor material from the receivers 128 and 134, respectively, to the chemical vapor deposition apparatus 148 via an outlet or line 146 in fluid communication with the chemical vapor deposition apparatus 148.

Distilling the precursor liquid may be accomplished by any suitable distillation technique. The distillation step may include simply heating the precursor material to a desired temperature and collecting, as a distillate, a purified precursor material. The distillation step may also include heating the precursor material to a first temperature below the boiling point of the precursor material (at a selected pressure), and then subsequently heating at a second temperature at about the boiling point of the precursor material (at a selected pressure). The distillate produced at the first, lower temperature may be collected along with the distillate from the distillation at the second temperature as purified precursor material. Alternatively, the distillate at the lower temperature, which may include lower boiling components, may be discarded (such as by evacuation or sent to the waste receptacle). It is not necessary to form an azeotropic mixture in the precursor material and then distill the precursor via azeotropic distillation to obtain a purified precursor material in accordance with the present invention.

The distillation may be carried out at any suitable temperature depending on the boiling point of the precursor material being used. The pressure inside the distillation vessel may be adjusted to lower the boiling point of the precursor material to prevent degradation of the precursor. The distillation vessel may be evacuated to provide a pressure below atmospheric pressure (760 torr) such as, for example, below about 200 torr, below about 150 torr, below about 100 torr, below about 50 torr, or even lower.

Additionally, the distillation vessel may be purged to remove oxygen from the system and apply a blanket of inert gas over the precursor liquid to prevent oxidation of the precursor. Suitable inert gases include, but are not limited to, nitrogen, helium, and the like.

Referring back to FIG. 1, a distillation system such as system 100 may be provided to supply a chemical vapor deposition apparatus with a substantially continuous flow of purified precursor material. By opening a valve 126 to lines 130 and 134, receivers 128 and 134 may be in fluid communication with the line 124, the condenser 120, the column 116, and the distillation vessel 108. The distillation vessel 108 and the receivers 128, 134 may be brought to a desired pressure by opening the valve 126 to lines 130 and 134, opening the valves 160 and 162 to the lines 164 and 166, respectively, and applying a vacuum to the system using a vacuum pump 156. Upon reaching the desired pressure, the vacuum 156 is shut off and the valves 160 and 162 are closed.

Precursor material is then distilled, and purified precursor vapor is condensed in the condenser 120 and passes through the line 124 to receivers 128 and 134. The valve 126 may be used to control the flow of purified precursor material to receivers 128 and 134 through lines 130 and 136, respectively. Receivers 128 and 134 may include a level sensor (e.g., level sensors 132 and 138, respectively, and upon reaching a desired level in a receiver, the valve 126 may be closed to stop the flow of purified precursor liquid to one of the receivers. Generally, the receivers are filled one at a time.

The system may contain a gas inlet or delivery line 170 in fluid communication with a gas source 168 and receivers 128 and 134 through delivery lines 176 and 178, respectively. The system may also include valves 172 and 174 to control the flow of gas into the receivers 128 and 134, respectively. After receivers the 128 and 134 are filled to a desired level with purified precursor material, the receivers may be pressurized by applying a gas blanket from the gas source 168 over the liquid in the receiver. The gas and pressure in the receiver may facilitate the flow of purified precursor from the receivers to the chemical vapor deposition apparatus. The gas applied to the receiver may be any suitable gas including, for example, helium, argon, hydrogen, and the like. A CVD apparatus typically employs a push pressure gas, such as helium, to facilitate the flow of precursor material whereby the carrier gas is mixed with the liquid precursor prior to entering a vaporizer or whereby the carrier gas is mixed with precursor vapor after the liquid precursor has been vaporized in a vaporizer. The apparatus shown in FIG. 2 may be connected to a carrier gas source on site at a CVD shop or plant and the push pressure gas used for the CVD apparatus may be used to pressurize the receivers to provide the push pressure to flow the precursor material to the CVD apparatus. The pressure in the receiver may be selected as desired for a particular purpose or intended use, such as to provide a desired flow rate from the receiver to a CVD apparatus. For example, the pressure may be applied with helium at about 20 to about 70 psig.

Purified precursor may be delivered to the chemical vapor deposition apparatus 148 by opening a delivery valve 144 to allow the purified precursor to flow through lines 140 or 142 through an outlet or delivery line 146 to the chemical vapor deposition apparatus. The purified precursor material is pushed from the pressurized receivers 128 or 134. To provide a continuous flow of purified precursor to the chemical vapor deposition apparatus, the purified precursor material is generally delivered from one receiver at a time. When the purified precursor is depleted to a selected volume, the system is transitioned to deliver precursor from the other receiver. For example, after supplying purified precursor material from receiver 128 and reaching a selected low level of purified precursor, the valve 144 is opened to line 142 to allow purified precursor from receiver 134 to flow into the outlet/line 146. For a selected period of time, the valve 144 also may remain open to the line 140 such that purified precursor is delivered from both receiver 128 and receiver 134. After the transition period, the delivery valve 144 is closed to line 140 and purified precursor is delivered solely from receiver 134.

A substantially continuous flow of purified precursor material may be provided by refilling the receiver having a depleted volume of purified precursor material while another full receiver delivers material to a CVD apparatus. For example, while purified material is being delivered from receiver 134, receiver 128 may be conditioned (such as by applying a vacuum to the receiver to provide a desired low pressure) and refilled by distilling precursor material and directing the flow into receiver 128. If necessary, the distillation vessel may be conditioned (e.g., by emptying any waste and evacuating the distillation vessel to provide a desired pressure level) and refilled with bulk precursor material prior to refilling an empty receiver. When the receiver 134 reaches a desired low level of precursor material, the system may be transitioned to deliver purified material from refilled receiver 128, and receiver 134 may then be refilled. To provide a substantially continuous flow, it may be desirable that the flow rate of the distillation process be about equal to the flow rate of purified precursor material to the high purity fluid processing system.

After distilling the precursor material, the distillation vessel may contain some undistilled material and waste residue. With reference to FIG. 1, the undistilled material and waste residue may be removed from the distillation vessel 108 into a waste receptacle 150. The waste may enter the waste receptacle 150 through a line 152 by opening a valve 154. The waste may be removed by any suitable method including by gravity, by vacuum, or by pressure. The waste could be forced through line 152 by introducing a push pressure into the distillation vessel through one of the receivers. For example, valve 126 could be opened to line 130 such that receiver 128 is in fluid communication with line 124, condenser 120, column 116, and the distillation vessel 108. Valve 172 may then be opened to line 176 and a push pressure may be introduced into the distillation vessel by introducing a gas from gas source 168 into receiver 128, which will then flow through lines 130, line 124, condenser 120, column 116 and into distillation vessel 108 to provide a pressure or flow of gas to push the waste into the waste receptacle. It will be appreciated that the distillation apparatus need not be emptied prior to refilling. Rather, precursor material may be introduced into the distillation vessel upon reaching a selected low level of material in the distillation vessel.

The distillation system may be automated and include any sensors (e.g., level sensors 112, 132, and 138 for monitoring the level of liquid in the distillation vessel and the receivers, spill sensors, leak sensors, or the like), temperature probes (e.g., probes 114 and 118), pneumatic banks (e.g., pneumatic control bank 180), and management of clean dry air for pneumatically actuated valves, interlocks, tubing, hardware (e.g., touch screen 182 and programmable logic controller 184), software, and/or circuitry necessary to operate the system and provide high purity liquid to meet the desired requirements of the high purity fluid processing system (e.g., chemical vapor deposition tool). The distillation system could be programmed as desired to control the operation of the system such as, for example, automatically supplying precursor material to the distillation vessel. As another example, the distillation of a precursor material could be stopped upon reaching a selected low level of material in the distillation vessel and not restarted until a signal is received that a receiver is at a selected low volume of purified precursor material and needs to be refilled.

As shown in FIGS. 1 and 2, the distillation system includes two receivers. The distillation system, however, may include one, two, three, or more receivers for collecting purified precursor material, and may include two or more receivers.

As shown in FIG. 1, the distillation system 100 is connected to chemical vapor deposition apparatus. The chemical vapor deposition apparatus may include any items necessary to deposit a film on a substrate such as, for example, a vaporizer, a vapor deposition reactor, and a delivery line to transport the purified precursor vapor to the deposition reactor. The purified precursor may be flowed to a CVD apparatus, combined with a carrier gas, flowed to a vaporizer, vaporized, and then flowed to a reactor for deposition on to a substrate. Alternatively, the purified precursor may be flowed to a CVD apparatus, vaporized, combined with a carrier gas, and the vapor/carrier gas or mixture may be flowed to a reactor for deposition on to a substrate. The purified precursor vapor is contacted with a substrate under conditions sufficient to deposit a thin film of a desired composition on the substrate. The vapor may be transported to the deposition reactor by the carrier gas used to push the liquid precursor to the deposition apparatus or an additional flow of gas may be provided to the chemical deposition system to transport the purified precursor vapor to the reactor. The chemical deposition apparatus may include more than one reactor, and the purified material from one distillation system may be sufficient to supply multiple reactors. The chemical vapor deposition apparatus may include any other instrumentation or devices as necessary to carry out the vapor deposition process.

It will be appreciated that the distillation system does not have to be connected to a chemical vapor deposition apparatus. Rather, the distillation system may serve as a “filling station” to collect purified precursor material in a receiver. A receiver could be disconnected from the distillation system and moved to a desired location where it may be hooked up for local delivery of purified precursor material.

The precursor material may be any material as desired for a particular purpose or intended use. A particularly suitable class of precursor materials includes silicone based precursors. Suitable silicone based precursors include, but are not limited to, alkyl silanes alkoxy silanes, siloxanes silsesquioxanes, and the like. An example of a suitable alkoxy silane is tetraethoxysilane (TEOS). Suitable silsesquioxanes include, for example, polyhedral oligomeric silsesquioxanes. Suitable siloxanes include, but are not limited to, cyclosiloxanes such as, for example, octamethylcyclotetrasiloxane, hexamethylcyclotetrasiloxane, tetramethylcyclotetrasiloxane, and the like. The method in accordance with the present invention may remove non-volatile impurities from such materials, which may prevent clogging of components in a CVD apparatus.

Prior to purification the precursor material by a method in accordance with the present invention, the bulk precursor material may have a purity, on a metals basis, of about 98% or higher, about 99% or higher, about 99.5% or higher, or even about 99.99% or higher. The method in accordance with the present invention allows a processor to purchase bulk precursor material of a relatively low purity (e.g., 98%) and purify the material as needed to supply to the processing system. Higher purity materials are generally more expensive, thus by purifying “on site” the cost of starting materials may be reduced.

### EXAMPLE

TEOS having a purity of 98% is purified via vacuum distillation as follows: TEOS is charged to a flask (distillation vessel) equipped with a condenser, which is connected to a receiver. The flask is evacuated and a nitrogen blanket is applied over the TEOS in the flask to provide a reduced pressure of about 0 to about 50 torr. The flask is heated to distill the TEOS and the boiling point of the TEOS is 45-47° C. After distillation, a residue is obtained in the distillation vessel and the distillate collected in the receiver is a purified TEOS.

Samples of TEOS are flowed through a D2000i series liquid mass flow controller available from Porter Instruments (Hatfield, Pa.). Pre-distilled, 98% pure TEOS is utilized as a control and is flowed through the controller. After flowing the control TEOS through the controller, the controller contains some crystals or oily residue, which could clog the controller. After the purified (distilled) TEOS precursor material is flowed through the controller, the controller does not contain any significant amount of crystal material or oil residue.

It is anticipated that certain changes may be made in the present invention without departing from the precepts involved herein. It is intended that all matter contained in the foregoing description shall be interpreted as illustrative and not in a limiting sense.

What is claimed is:

1. A method for treating a precursor material for use in a chemical vapor deposition system comprising:
providing a precursor material suitable for chemical vapor deposition; and
distilling the precursor material to provide, as a distillate, a purified precursor material, from which at least one non-volatile component, at least one metal impurity, or a combination thereof has been removed.

2. The method according to claim 1, wherein distilling the precursor material is carried out by a distillation method other than azeotropic distillation.

3. The method according to claim 1, wherein the purified precursor material has a higher purity, on a metals basis, than the precursor material.

4. The method according to claim 1, wherein the distilling step is carried out at a pressure below atmospheric pressure.

5. The method according to claim 1, wherein the distilling step is carried out at a pressure below about 150 torr.

6. The method according to claim 1, wherein the distilling step comprises:
heating the precursor material at a first temperature below the boiling point of the precursor material to separate lower boiling components from the precursor material; and
heating the precursor material at a second temperature sufficient to distill the precursor material and provide a purified precursor material.

7. The method according to claim 1, wherein the precursor material comprises at least one silane, at least one siloxane, or combinations of two or more thereof.

8. The method according to claim 7, wherein the precursor material comprises at least one siloxane chosen from at least one polyhedral oligomeric silsesquioxane, octamethylcyclotetrasiloxane, hexamethylcyclotetrasiloxane, tetramethylcyclotetrasiloxane, or combinations of two or more thereof.

9. The method according to claim 7, wherein the precursor material comprises tetraethoxysilane.

10. The method according to claim 1, wherein the precursor material has an initial purity of at least about 98% on a metals basis.

11. A purified precursor obtained by the method of claim 1.

12. A method for depositing a coating on a substrate by chemical vapor deposition comprising:
delivering a purified precursor obtained by the method of claim 1 to a chemical vapor deposition apparatus;
vaporizing the purified precursor; and
contacting the purified precursor vapor with a substrate to deposit a desired coating on the substrate.

13. The method according to claim 12, wherein the purified precursor is obtained by employing a distillation system comprising at least one receiver for receiving purified precursor material, and a delivery line for delivering purified precursor material from the at least one receiver to the chemical vapor deposition apparatus.

14. The method according to claim 13, comprising filling the receiver with a distillate comprising a purified precursor material and pressurizing the at least one receiver to facilitate delivery of the liquid to the chemical vapor deposition apparatus.

15. The method according to claim 12, wherein the purified precursor is obtained by employing a distillation apparatus comprising a first receiver for receiving purified precursor material, a second receiver for receiving purified precursor material, and a delivery line connected to each of the first and second receivers, the delivery line being in fluid communication with the chemical vapor deposition apparatus for delivering purified precursor material to the chemical vapor deposition apparatus.

16. The method according to claim 15, wherein a substantially continuous flow of purified precursor material is provided to the chemical vapor deposition apparatus by:
(a) delivering purified precursor material to the chemical vapor deposition apparatus from the first receiver until the first receiver contains a selected depleted volume of purified precursor material;
(b) delivering purified precursor material to the chemical vapor deposition apparatus from the second receiver upon reaching the selected depleted volume in the first receiver;
(c) refilling the first receiver;
(d) depleting the volume of purified precursor material in the second receiver to a selected depleted volume;
(e) delivering purified precursor material from the refilled first receiver upon reaching the selected depleted volume in the second receiver;
(f) refilling the second receiver; and
(g) repeating steps (a)-(f).

17. The method of claim 16, wherein precursor material is introduced into the distillation vessel when the purified precursor material in the first or second receiver is depleted to a selected volume of purified precursor material, and the precursor material is distilled to provide a purified precursor material.

18. A chemical vapor deposition system comprising:
a distillation system for purifying a precursor material; and
a chemical vapor deposition apparatus; wherein the distillation system comprises a distillation vessel; a fluid inlet in fluid communication with the distillation vessel for delivering a precursor material to the distillation vessel; a condenser; at least one receiver for receiving a purified precursor material obtained by distilling a precursor material; a gas inlet in fluid communication with the at least one receiver for introducing a gas into the at least one receiver and pressurizing the at least one receiver to facilitate the flow of the purified precursor material to the high purity fluid processing system; and an outlet in fluid communication with the chemical vapor deposition apparatus.
